(19) United States
(12) Patent Application Publication
(10) Pub. No.: US 2025/0203803 A1
(43) Pub. Date: Jun. 19, 2025

(54) ELECTRONIC DEVICE AND EXPANSION ASSEMBLY THEREOF

(71) Applicant: Wistron Corporation, New Taipei City (TW)

(72) Inventors: Ching-Hao CHEN, New Taipei City (TW); Yu-Chen LIN, New Taipei City (TW); Li-Shu CHEN, New Taipei City (TW)

(21) Appl. No.: 18/592,648

(22) Filed: Mar. 1, 2024

(30) Foreign Application Priority Data
Dec. 13, 2023 (TW) 112148611

(51) Int. Cl. H05K 7/14

(52) U.S. Cl. CPC H05K 7/1487; H05K 7/1489

(57) ABSTRACT

An electronic device includes an expansion assembly. The expansion assembly includes a first baffle, a second baffle, and a baffle assembly. The first baffle is opposite to the second baffle. The baffle assembly is disposed between the first baffle and the second baffle. The baffle assembly has two side plates and a plurality of elastic members. The two side plates face each other and define a card insertion area. The plurality of elastic members are respectively disposed on each of the two side plates. Each elastic member includes a docking part and a supporting part. The elastic members are respectively disposed on each of the two side plates via the docking parts. The supporting parts are projected from one of the two side plates in the card insertion areas. Electronic components of different thicknesses in the card insertion areas respectively abut against the supporting parts.

### CROSS-REFERENCE TO RELATED APPLICATION

This non-provisional application claims priority under 35 U.S.C. § 119(a) to patent application No. 112148611 filed in Taiwan, R.O.C. on Dec. 13, 2023, the entire contents of which are hereby incorporated by reference.

### BACKGROUND

### Technical Field

The instant disclosure is related to an electronic device and an expansion assembly thereof, and in particular, an expansion assembly allowing for insertion of expansion cards of different thicknesses.

### Related Art

A plurality of expansion modules are installed in a server, and a plurality of expansion cards are provided in each expansion module. Generally, the expansion module has a fixed structure that is supported on a side edge of the expansion card, but the fixed structure cannot be used to expansion cards of different thicknesses, so that expansion cards of different thicknesses cannot be inserted in a same expansion module.

### SUMMARY

In view of this, according to some embodiments, an expansion assembly is provided, including a first baffle, a second baffle, and a baffle assembly. The first baffle is opposite to the second baffle. The baffle assembly includes two side plates opposite to each other and a plurality of elastic members disposed on each of the two side plates respectively. The two side plates are connected to the first baffle and the second baffle, and each of the elastic member includes a supporting part. The supporting parts project from one of the two side plates towards the other one of the two side plates.

In some embodiments, each of the two side plates includes an elongated hole and a first slide rail. The first slide rail projects from one side surface of one of the two side plate towards the other one of the two side plates. The first slide rail is adjacent to the elongated hole. The supporting part of one of the plurality of elastic members is deformably disposed in the elongated hole of one of the two side plates.

In some embodiments, each of the plurality of elastic members includes two docking parts. The two docking parts are respectively connected to two ends of the supporting part. Each of the two side plates includes two fixing parts and one elongated hole. The two fixing parts are respectively disposed on two ends of each of the two side plates. The elongated hole is provided between the two fixing parts. The two docking parts are disposed on the two fixing parts, respectively. The supporting part of each of the plurality of elastic members is deformably disposed in the elongated hole.

In some embodiments, the supporting part of each of the plurality of elastic member includes a plurality of outer protrusion parts and a plurality of inner protrusion parts arranged alternately in sequence. Each of the plurality of outer protrusion parts projects from one side surface of one of the two side plates towards the other one of the two side plates, and each of the plurality of inner protrusion part projects from the other side surface of one of the two side plates away from the other one of the two side plates.

In some embodiments, each of the plurality of elastic members includes a base and an extension arm. The extension arm extends from the base. The supporting part extends from one side edge of the extension arm. An angle is formed between the supporting part and the extension arm.

In some embodiments, the supporting part has an inclined surface. An angle is formed between the inclined surface and the extension arm.

In some embodiments, each of the two side plates includes two elongated holes arranged in sequence in a direction. Each of the plurality of elastic members includes two extension arms extending from the base. Each of the two extension arms is provided with the supporting part. The two supporting parts are deformably disposed in the two elongated holes, respectively.

In some embodiments, each of the plurality of elastic members includes a docking plate. The docking plate is disposed on one side surface of one of the two side plates. The supporting part projects from the docking plate towards the other one of the two side plates.

In some embodiments, two ends of the supporting part are connected to the docking plate to form an elastic arm.

In some embodiments, one end of the supporting part is connected to the docking plate, and the other end of the supporting part is a free end, which forms a cantilever.

In some embodiments, each of the plurality of elastic members includes a second slide rail. The second slide rail projects from the docking plate towards the other one of the two side plates. The second slide rail is adjacent to the supporting part.

In some embodiments, each of the plurality of elastic members includes a docking plate and a plurality of supporting parts. The docking plate is disposed on one side surface of one of the two side plates. One of the supporting parts projects from the docking plate towards the other one of the two side plates. Another supporting part adjacent to the supporting part projects from the docking plate away from the other one of the two side plates.

In some embodiments, each of the two side plates includes an elongated hole. The supporting part of the elastic member is deformably disposed in the elongated hole.

In some embodiments, two ends of the supporting part are connected to the docking plate to form an elastic arm.

In some embodiments, one end of the supporting part is connected to the docking plate, and the other end of the supporting part is a free end, which forms a cantilever.

In some embodiments, an electronic device is provided, including an expansion assembly and an electronic component. The expansion assembly includes a first baffle, a second baffle, and a baffle assembly. The second baffle is opposite to the first baffle. The baffle assembly includes two side plates opposite to each other and a plurality of elastic members disposed on each of the two side plates respectively. The two side plates are disposed between the first baffle and the second baffle. The first baffle, the second baffle, and the two side plates define a card insertion area. Each of the elastic member includes a supporting part. The supporting parts project from one of the two side plates towards the other one of the two side plates. The electronic component is used to be accommodated in the card insertion area and supported or clamped by the elastic members.

In some embodiments, the electronic component is a first expansion card or a second expansion card. The supporting parts of the plurality of elastic members are used to support a bottom of the first expansion card or holding two sides of the second expansion card.

In some embodiments, the side plate includes an elongated hole and a fixing part. The elongated hole is adjacent to the fixing part. The elastic member includes a docking part. The docking part is disposed on the fixing part. The supporting part is deformably disposed in the elongated hole.

In some embodiments, the elastic member includes a docking plate. The docking plate is disposed on one side surface of one of the two side plates. The supporting part projects from the docking plate towards the other one of the two side plates.

In some embodiments, the elastic member includes a docking plate and a plurality of supporting parts. The docking plate is disposed on one side surface of one of the two side plates. One of the supporting parts projects from the docking plate towards the other one of the two side plates. Another supporting part adjacent to the supporting part projects from the docking plate away from the other one of the two side plates.

In conclusion, according to some embodiments, the supporting parts of the elastic members are disposed on the plurality of side plates of the baffle assembly, so that the supporting parts are respectively located in card insertion areas to allow electronic components of different thicknesses to be separately inserted in card insertion areas in a same area of a same expansion assembly.

### BRIEF DESCRIPTION OF THE DRAWINGS

FIG. 1 is a schematic diagram of an appearance of an electronic device having an expansion assembly according to some embodiments;

FIG. 2 is a schematic exploded view of an expansion assembly having a plurality of baffle assemblies according to some embodiments, including elastic members;

FIG. 3 is a schematic exploded view of a baffle assembly according to some embodiments, including elastic members;

FIG. 4A is a schematic diagram of a partial appearance of an electronic device according to some embodiments, in which a first baffle is removed to clearly show a state of electronic components being inserted in a card insertion area, the electronic components abutting against elastic members;

FIG. 4B is a schematic partial front view of an electronic device according to some embodiments, showing a state of first expansion cards being inserted in a card insertion area, the first expansion cards abutting against elastic members;

FIG. 4C is a schematic partial font view of an electronic device according to some embodiments, showing a state of a second expansion card being inserted in a card insertion area, the second expansion card abutting against elastic members;

FIG. 5 is a schematic partial top view of an electronic device according to some embodiments, showing a state of an electronic component being prepared to be inserted in a card insertion area and abutting against elastic members;

FIG. 6 is a schematic partial top view of an electronic device according to some embodiments, showing a state of an electronic component being inserted in a card insertion area and abutting against elastic members;

FIG. 7 is a schematic exploded view of a baffle assembly according to some embodiments, including elastic members;

FIG. 8 is a schematic partial top view of an electronic device according to some embodiments, showing a state of an electronic component being prepared to be inserted in a card insertion area and abutting against elastic members;

FIG. 9 is a schematic partial top view of an electronic device according to some embodiments, showing a state of electronic components being inserted in card insertion areas and abutting against elastic members;

FIG. 10 is a schematic front exploded view of a baffle assembly according to some embodiments, including an elastic member;

FIG. 11 is a schematic rear exploded view of a baffle assembly according to some embodiments;

FIG. 12 is a schematic partial top view of an electronic device according to some embodiments, showing a state of an electronic component being prepared to be inserted in a card insertion area and abutting against elastic members;

FIG. 13 is a schematic partial top view of an electronic device according to some embodiments, showing a state of electronic components being inserted in card insertion areas and abutting against elastic members;

FIG. 14 is a schematic exploded view of a baffle assembly according to some embodiments, having an elastic member including a plurality of supporting parts (which are of a cantilever structure) arranged in a staggered manner;

FIG. 15 is a schematic partial top view of an electronic device according to some embodiments, showing a state of electronic components being inserted in card insertion areas and abutting against supporting parts, which have a cantilever structure each;

FIG. 16 is a schematic exploded view of a baffle assembly according to some embodiments, having an elastic member including a plurality of supporting parts (which are of an elastic arm structure) arranged in a staggered manner; and

FIG. 17 is a schematic partial top view of an electronic device according to some embodiments, showing a state of electronic components being inserted in card insertion areas and abutting against supporting parts, which have an elastic arm structure each.

### DETAILED DESCRIPTION

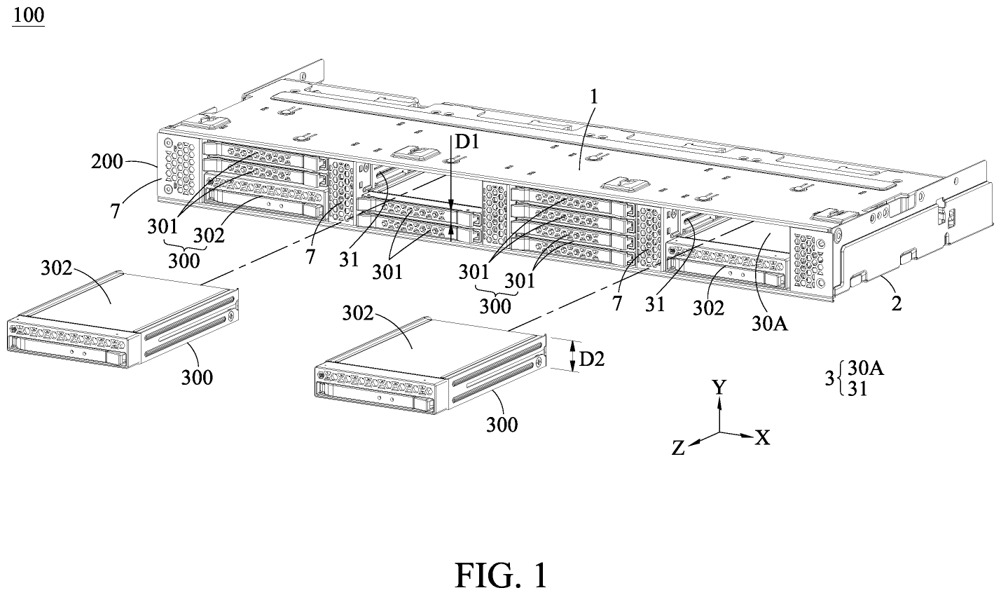

FIG. 1 is a schematic diagram of an appearance of an electronic device 100. The electronic device 100 includes an expansion assembly 200. One or more electronic components 300 are installed in the expansion assembly 200. In some embodiments, the electronic component 300 is a first expansion card 301 or a second expansion card 302. The first expansion card 301 or the second expansion card 302 may be, but not limited to, a hard disk, a graphics card, or another device, for example, a Peripheral Component Interconnect Express (PCI Express, PCIe) card. The hard disk is of E3 specification and is suitable for a 2U computer case (the height of a rack server is expressed in U. 1 U is equal to 1.75 inches or 44.45 mm). The first expansion card 301 has a first thickness D1, the second expansion card 302 has a second thickness D2, and the second thickness D2 of the second expansion card 302 is approximately twice that of the first expansion card 301, and is not limited thereto.

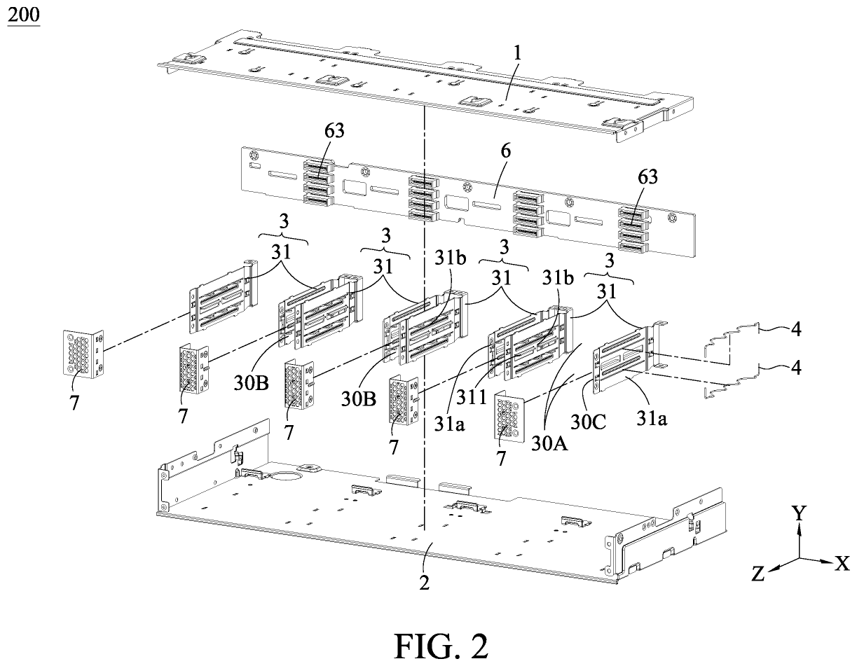

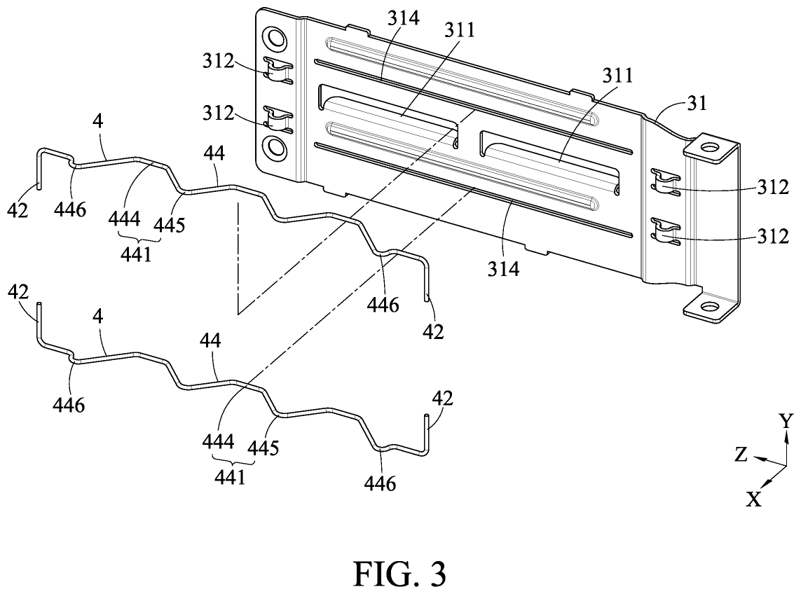

Refer to FIG. 2 and FIG. 3. FIG. 2 is a schematic exploded view of an expansion assembly 200 including a plurality of baffle assemblies 3. FIG. 3 is a schematic exploded view of a baffle assembly 3, including elastic members 4. The expansion assembly 200 includes a first baffle 1, a second baffle 2, and a baffle assembly 3. The first baffle 1 is an upper housing, and the second baffle 2 is a lower housing. The second baffle 2 is opposite to and spaced apart from the first baffle 1. The baffle assembly 3 is disposed between the first baffle 1 and the second baffle 2. The baffle assembly 3 includes two side plates 31 and a plurality of elastic members 4. The side plates 31 include a first side plate 31a and a second side plate 31b opposite to each other. The first side plate 31a and the second side plate 31b face each other and jointly define a card insertion area 30A with the first baffle 1 and the second baffle 2. The card insertion area 30A is used to accommodate the electronic component 300. The elastic members 4 each include a docking part 42 and a supporting part 44. The elastic members 4 are symmetrically disposed on the first side plate 31a and the second side plate 31b, respectively. The supporting part 44 projects from one side plate 31 towards the other side plate 31 in the card insertion area 30A. In other words, the supporting part 44 of the elastic member 4 disposed on the first side plate 31a projects from the first side plate 31a towards the second side plate 31b, and the supporting part 44 is located in the card insertion area 30A. The supporting part 44 of the elastic member 4 disposed on the second side plate 31b projects from the second side plate 31b towards the first side plate 31a, and the supporting part 44 is located in the card insertion area 30A. The card insertion area 30A has an insertion slot 30C communicated with the card insertion area 30A. The insertion slot 30C is defined by one side edge of the first side plate 31a, one side edge of the second side plate 31b, one side edge of the first baffle 1, and one side edge of the second baffle 2. The electronic component 300 can be inserted in the card insertion area 30A through the insertion slot 30C and is disposed in the electronic device 100.

To describe the present application more clearly, in the schematic diagrams provided in the present application, an arrangement direction of the side plates 31 side by side is referred to as a first axis X direction (that is, an X-axis direction shown in the diagrams, or a left-right direction). An arrangement direction of the first baffle 1 and the second baffle 2 is referred to as a second axis Y direction (that is, a Y-axis direction shown in the diagrams, or an up-down direction). A direction that is parallel to the side plates 31 and for insertion of the electronic component 300 is referred to as a third axis Z direction (that is, a Z-axis direction shown in the diagrams, or a front-rear direction). In some embodiments, the first axis X is an X-axis of a three-dimensional coordinate system, the second axis Y is a Y-axis of the three-dimensional coordinate system, and the third axis Z is a Z-axis of the three-dimensional coordinate system.

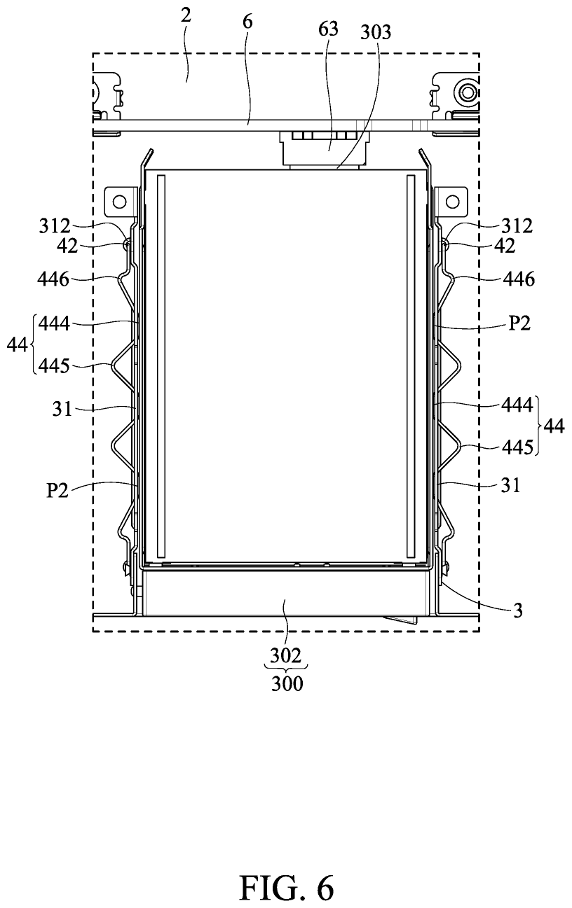

In some embodiments, the expansion assembly 200 further includes a back plate 6. The back plate 6 may be a circuit board. The back plate 6 is located between the first baffle 1 and the second baffle 2, and is disposed at a position away from the insertion slot 30C. The back plate 6 includes a connecting portion 63. The connecting portion 63 may include at least one connector slot. The connecting portion 63 is aligned with the card insertion area 30A. When the electronic component 300 is inserted in the card insertion area 30A along the third axis Z direction, a connecting port 303 (shown in FIG. 6) at the back end of the electronic component 300 is docked to the connecting portion 63.

In some embodiments, the electronic device 100 includes a plurality of baffle assemblies 3, and the baffle assemblies 3 are arranged alternately. The side plate 31 of one baffle assembly 3 and the side plate 31 of another baffle assembly 3 are adjacent to and face away from each other. In other words, the first side plate 31a of one baffle assembly 3 and the second side plate 31b of another baffle assembly 3 are adjacent to and face away from each other. The first side plate 31a and the second side plate 31b facing away from each other define a gap area 30B. The gap areas 30B and the card insertion areas 30A are arranged alternately. In some embodiments, the electronic device 100 includes an air baffle 7. The air baffle 7 is fixed between the first baffle 1 and the second baffle 2, is combined with the first side plate 31a and the second side plate 31b facing away from each other, and covers the gap area 30B. The air baffle 7 is located adjacent to the insertion slot 30C.

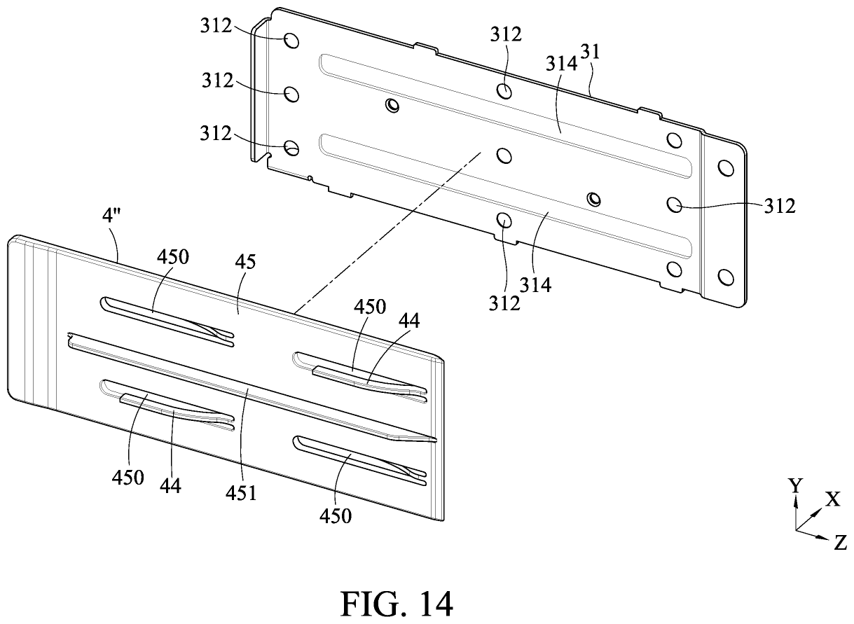

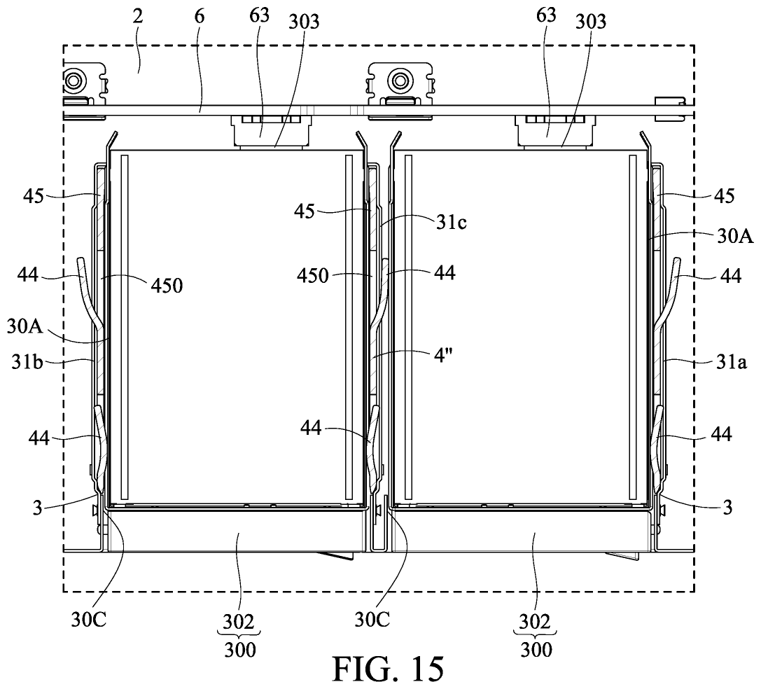

In some embodiments, as shown in FIG. 2, the expansion assembly 200 includes four baffle assemblies 3, which include, but are not limited to, four first side plates 31a and four second side plates 31b. In some embodiments, the expansion assembly 200 may use only one baffle assembly 3, which includes one first side plate 31a and one second side plate 31b. In a case that the expansion assembly 200 includes a plurality of baffle assemblies 3, the baffle assemblies 3 are arranged between the first baffle 1 and the second baffle 2 alternately. In some embodiments, to provide more use patterns, in the baffle assembly 3, a third side plate 31c is used to replace the first side plate 31a and the second side plate 31b, and two adjacent baffle assemblies 3 may share one third side plate 31c (as shown in FIG. 14 and FIG. 15, as described later).

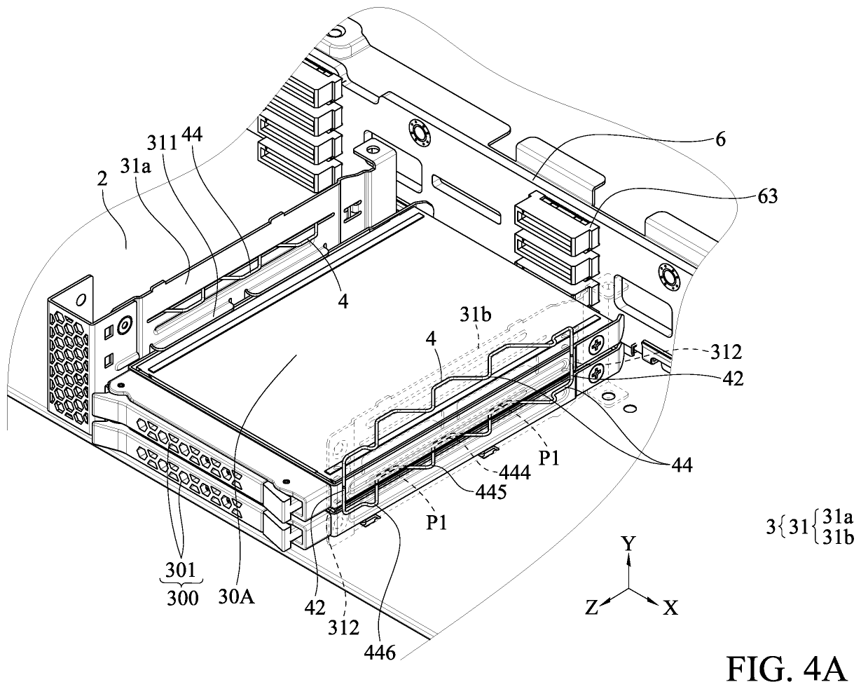

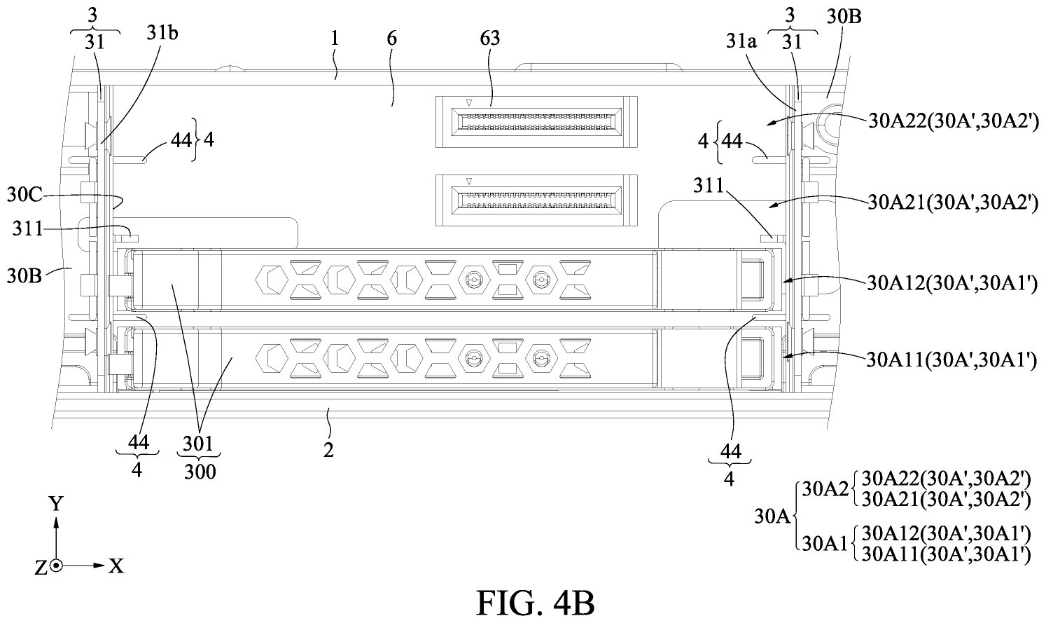

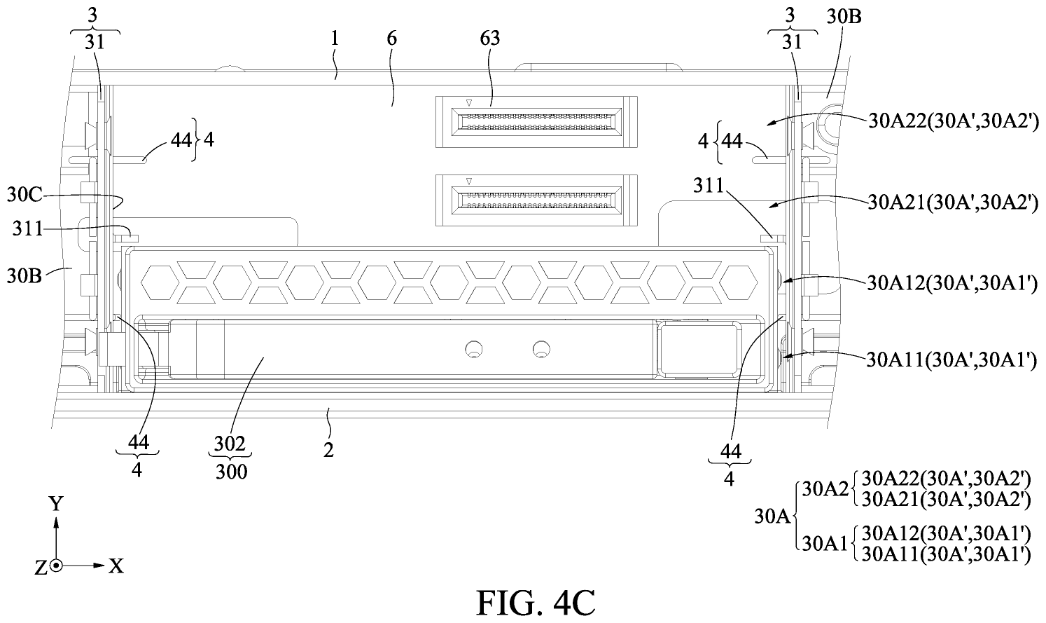

Refer to FIG. 4A to FIG. 4C. FIG. 4A is a schematic partial diagram of an appearance of an electronic device 100, in which a first baffle 1 is removed to clearly show a state of electronic components 300 being inserted in a card insertion area 30A, the electronic components 300 abutting against elastic members 4. FIG. 4B is a schematic partial font view of an electronic device 100, showing a state of first expansion cards 301 being inserted in a card insertion area 30A, the first expansion card 301 abutting against elastic members 4. FIG. 4C is a schematic partial font view of an electronic device 100, showing a state of a second expansion card 302 inserted in a card insertion area 30A, the second expansion card 302 abutting against elastic members 4. The card insertion area 30A can be defined by elastic members 4 as a first card insertion area 30A11, a second card insertion area 30A12, a third card insertion area 30A21, and a fourth card insertion area 30A22 along a second axis Y direction. The first card insertion area 30A11 and the second card insertion area 30A12 form a first group of card insertion area 30A1′. The third card insertion area 30A21 and the fourth card insertion area 30A22 form a second group of card insertion area 30A2′. Four electronic components 300 (which are the first expansion cards 301) or two electronic components 300 (which are the second expansion cards 302) may be inserted in the four card insertion areas 30A, respectively. This is not limited thereto. In some embodiments, the card insertion area 30A of the baffle assembly 3 may be defined by the elastic members 4 as at least two card insertion areas 30A′. Two electronic components 300 (which are the first expansion cards 301) or one electronic component 300 (which is the second expansion card 302) can be inserted in the two card insertion areas 30A′, respectively. This is not limited thereto.

Refer to FIG. 3 to FIG. 4B. In some embodiments, the side plate 31 includes a first slide rail 311. The first slide rail 311 is a transverse plate extending along a third axis Z direction, and projects from one side surface of the side plate 31 towards the other side plate 31 along a first axis X direction. Specifically, the first slide rails 311 may respectively project from one side surface of the first side plate 31a and one side surface of the second side plate 31b towards each other. In other words, each first slide rail 311 projects from one side surface of the side plate 31 towards the card insertion area 30A, so that the electronic component 300 can be firmly positioned after being inserted in the card insertion area 30A. In some embodiments, the first slide rail 311 may define the card insertion area 30A as a card insertion area 30A1 and a card insertion area 30A2 together with the first side plate 31a and the second side plate 31b. In some embodiments, two elastic members 4 may be disposed on two sides of the first slide rail 311 in the second axis Y direction. In other words, one elastic member 4 is disposed between the first slide rail 311 and the first baffle 1, and the other elastic member 4 is disposed between the first slide rail 311 and the second baffle 2. The supporting part 44 of the elastic member 4 may define, together with the first side plate 31a and the second side plate 31b, the card insertion area 30A1 as the first card insertion area 30A11 and the second card insertion area 30A12, and the card insertion area 30A2 as the third card insertion area 30A21 and the fourth card insertion area 30A2. When the first expansion cards 301 are inserted in the first card insertion area 30A11 and the second card insertion area 30A12, the supporting parts 44 of the elastic members 4 support the bottom of the first expansion card 301 in the second card insertion area 30A12. The third card insertion area 30A21 and the fourth card insertion area 30A22 each can accommodate the first expansion card 301. In this case, the first slide rail 311 supports the bottom of the first expansion card 301 in the third card insertion area 30A21. Another state in use is that the second expansion cards 302 are inserted in the third card insertion area 30A21 and the fourth card insertion area 30A22 (namely, the card insertion area 30A2). The first slide rails 311 support the bottom of the second expansion cards 302, and the elastic members 4 clamps side edges of the second expansion cards 302.

The use of the first slide rails 311 on the first side plate 31a and the second side plate 31b above is merely an example. In some embodiments, the first slide rails 311 on the first side plate 31a and the second side plate 31b can be omitted, but the supporting parts 44 of the elastic member 4 can be disposed at corresponding positions, so that the supporting parts 44 may abut against the bottom of the first expansion card 301 or the second expansion card 302, to provide support.

Refer to FIG. 1 and FIG. 4B. In some embodiments, different quantity of first expansion cards 301, second expansion cards 302, or a combination of the first expansion card 301 and the second expansion card 302 can be inserted arbitrarily in the card insertion area 30A. As shown in FIG. 1, two second expansion cards 302 can be separately inserted in a card insertion area 30A on the rightmost. In other words, one second expansion card 302 is inserted in each of the first card insertion area 30A11 and the second card insertion area 30A12 (namely, the card insertion area 30A1), and another second expansion card 302 is inserted in each of the third card insertion area 30A21 and the fourth card insertion area 30A22 (namely, the card insertion area 30A2). This is not limited thereto. As shown in FIG. 1, four first expansion cards 301 can be separately inserted in a second card insertion area 30A from the right to the left. In other words, the first expansion cards 301 are inserted in the first card insertion area 30A11, the second card insertion area 30A12, the third card insertion area 30A21, and the fourth card insertion area 30A22, respectively. As shown in FIG. 1, for a second card insertion area 30A from the left to the right, one first expansion card 301 is inserted in each of the first card insertion area 30A11 and the second card insertion area 30A12. One second expansion card 302 is inserted in each of the third card insertion area 30A21 and the fourth card insertion area 30A22. As shown in FIG. 1, for a card insertion area 30A on the leftmost, one second expansion card 302 is inserted in each of the first card insertion area 30A11 and the second card insertion area 30A12 (namely, the card insertion area 30A1), and one first expansion card 301 is inserted in each of the third card insertion area 30A21 and the fourth card insertion area 30A22. In this way, first expansion cards 301 or second expansion cards 302 of different sizes can be inserted in the card insertion areas 30A in a same area of the same expansion assembly 200.

In some embodiments, to provide a firm positioning effect for the electronic component 300 in the card insertion area 30A, the elastic member 4 is provided with a continuous bending structure 441, which is used to abut against the electronic component 300. Each elastic member 4 includes two docking parts 42 and a supporting part 44 connected between the two docking parts 42. The two docking parts 42 and the supporting part 44 have an appearance generally in a shape of “n” when viewed from the first axis X direction. The supporting part 44 is provided with a continuous bending structure 441. The continuous bending structure 441 includes outer protrusion parts 444 and inner protrusion parts 445 arranged alternately in sequence. The outer protrusion parts 444 project from the first side plate 31a and the second side plate 31b in the card insertion area 30A. The inner protrusion parts 445 project from the first side plate 31a and the second side plate 31b in the gap area 30B. The outer protrusion parts 444 and the inner protrusion parts 445 are arranged on the same horizontal line along the third axis Z direction. The outer protrusion parts 444 and the inner protrusion parts 445 are generally in a wave shape when viewed from the second axis Y direction. The outer protrusion parts 444 are trapezoidal, and the inner protrusion parts 445 and curved arc parts 446 are semicircular. This is not limited thereto. In other words, each outer protrusion part 444 projects from one side surface of the side plate 31 towards the other side plate 31. Each inner protrusion part 445 projects from the other side surface of the side plate 31.

In some embodiments, both the outer protrusion parts 444 and the inner protrusion parts 445 are made of a metal material of a same spring. A quantity of the outer protrusion parts 444 is an integer, and a quantity of the inner protrusion parts 445 is an integer, for example, but not limited to two, three, or four. When coming into contact with the electronic component 300, the outer protrusion parts 444 can provide a grounding effect to prevent electromagnetic interference (EMI) and electrostatic discharge (ESD). In addition, the continuous bending structure 441 includes a plurality of curved arc parts 446, which are located between the outer protrusion parts 444 and the docking parts 42 to enhance structural strength.

In some embodiments, the side plate 31 is a vertical plate and is disposed in the second axis Y direction. The side plate 31 includes two fixing parts 312 and an elongated hole 314. A long axis direction of the elongated hole 314 is arranged in a same horizontal direction as a card insertion direction of the card insertion area 30A. The two fixing parts 312 are respectively located on two sides of the elongated hole 314 and are disposed on two ends of the side plate 31. The two docking parts 42 of the elastic member 4 are disposed in the two fixing parts 312, respectively. The supporting part 44 of the elastic member 4 deformably penetrates through the elongated hole 314. Specifically, the outer protrusion part 444 of the supporting part 44 projects from one side plate 31 towards the other side plate 31 and is located in the card insertion area 30A. The inner protrusion part 445 of the supporting part 44 projects from one side plate 31 in a direction away from the other side plate 31 and is located in the gap area 30B. In this case, the outer protrusion part 444 of each elastic member 4 is located at a first position P1 (as shown in FIG. 4A). In this way, a position of the outer protrusion part 444 is restricted by the elongated hole 314, to prevent the outer protrusion part 444 from falling off from the elongated hole 314. In some embodiments, the elastic member 4 is disposed on one side surface of the side plate 31 (not indicated) via the docking part 42. The supporting part 44 penetrates through the elongated hole 314 and projects from the other side surface of the side plate 31 (not indicated) and is located in the card insertion area 30A. The first slide rail 311 is located adjacent to the elongated hole 314.

In some embodiments, the baffle assembly 3 includes two elastic members 4. The side plate 31 includes two elongated holes 314 arranged in the second axis Y direction. The supporting parts 44 of the two elastic members 4 are deformably disposed in the two elongated holes 314, respectively.

In some embodiments, the docking part 42 is a rod 42 (where the rod 42 is given a same sign as the docking part 42 below). The rod 42 is perpendicular to the outer protrusion part 444 and the inner protrusion part 445. The fixing part 312 may be a curved ring 312 (the curved ring 312 is given a same sign as the fixing part 312 below). When the elastic member 4 is disposed on the side plate 31, two rods 42 are inserted in two curved rings 312. In some embodiments, the side plate 31 includes at least one elongated hole 314 and a fixing part 312. The elongated hole 314 is located adjacent to the fixing part 312.

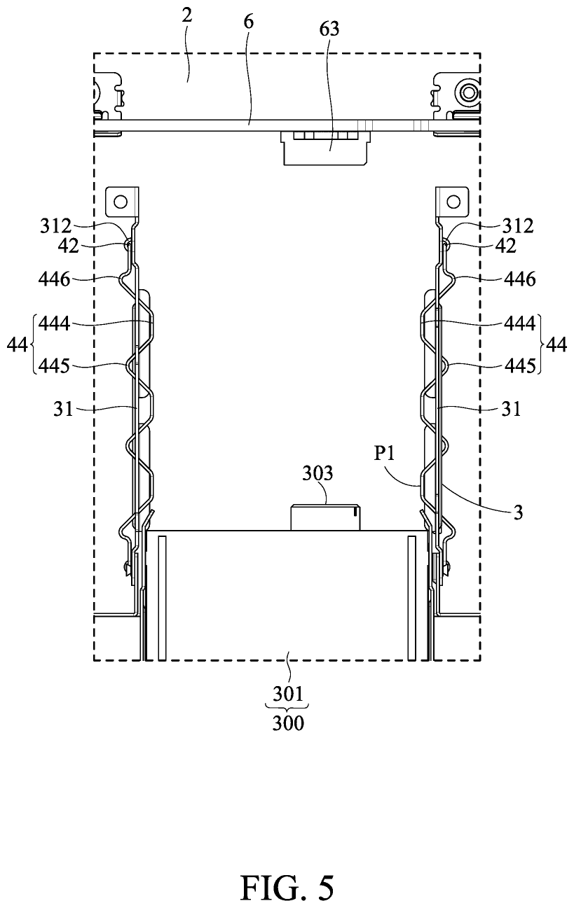

Refer to FIG. 1 and FIG. 3 to FIG. 6. FIG. 5 is a schematic partial top view of an electronic device 100, and shows a state of an electronic component 300 being prepared to be inserted in a card insertion area 30 A and abutting against elastic members 4. FIG. 6 is a schematic partial top view of an electronic device 100, and shows a state of an electronic component 300 being inserted in a card insertion area 30A and abutting against elastic members 4. In some embodiments, the electronic device 100 further includes an electronic component 300. When the electronic component 300 is inserted in the card insertion area 30A, two sides of the electronic component 300 respectively abut against the supporting parts 44 of the elastic members 4. In other words, the supporting part 44 has a similar supporting function or holding function for electronic components 300 of different thickness. When the first expansion card 301 is inserted in the card insertion area 30A, the supporting parts 44 abut against the bottom of the first expansion card 301 to provide a supporting function (as shown in FIG. 4B and FIG. 5). When the second expansion card 302 is inserted in the card insertion area 30A, the second expansion card 302 pushes against the supporting parts 44 to enable the supporting parts 44 to deform elastically and abut against side edges of the second expansion card 302 to provide a holding function (as shown in FIG. 4C and FIG. 6). In this way, the supporting part 44 supports or holds (or clamps) the electronic component 300. That the supporting parts 44 abut against side edges of or the bottom of two sides of the electronic component 300 is merely an example. This is not limited thereto. In some embodiments, the supporting part 44 abuts against various parts of the electronic component 300, such as, but not limited to, a plane or a corner of a front end or a back end of the electronic component 300.

Refer to FIG. 1, FIG. 3, FIG. 4A, FIG. 4B, and FIG. 5. In an example in which the electronic component 300 is the first expansion card 301, when the first expansion card 301 is inserted in the card insertion area 30A, the supporting parts 44 of the elastic members 4 are located at the first position P1 and support at the bottom of two sides of the first expansion card 301. The outer protrusion parts 444 of the supporting parts 44 firmly support the first expansion card 301.

Refer to FIG. 1, FIG. 3, FIG. 4A, FIG. 4C, and FIG. 6. In an example in which the electronic component 300 is the second expansion card 302, because the thickness of the second expansion card 302 is approximately twice the thickness of the first expansion card 301, and the thickness of each card insertion area 30A′ is substantially used to match the thickness of the first expansion card 301. When the second expansion card 302 is inserted in the card insertion area 30A, two sides of the second expansion card 302 push against the supporting parts 44 of the elastic members 4, and the supporting parts 44 move from the first position P1 to a second position P2 (as shown in FIG. 6). The supporting parts 44 move from the card insertion area 30A to the gap area 30B. The outer protrusion parts 444 of the supporting parts 44 of the elastic members 4 can firmly clamp two sides of the second expansion card 302. In this way, the first expansion card 301 (as shown in FIG. 5), the second expansion card 302 (as shown in FIG. 6), or both can be flexibly mounted in the card insertion area 30A of a same expansion assembly 200.

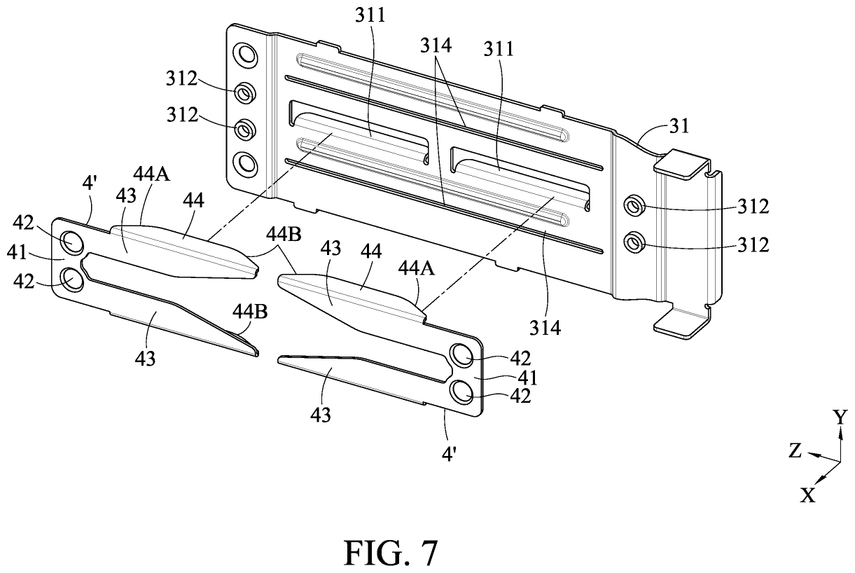

FIG. 7 is a schematic exploded view of a baffle assembly 3, including elastic members 4′. In some embodiments, each elastic member 4′ includes a base 41, extension arms 43, and supporting parts 44. The elastic member 4′ is disposed on the side plate 31 via the base 41. The extension arm 43 extends from the base 41 along a plus third axis Z direction or a minus third axis Z direction. The supporting part 44 extends and bends from one side edge of the extension arm 43. An angle is formed between the supporting part 44 and the extension arm 43.

The supporting part 44 extends from one side edge of the extension arm 43 along a minus first axis X direction opposite to a plus first axis X direction. The supporting part 44 is used to abut against the bottom of the electronic component 300. In some embodiments, the end of the supporting part 44 located adjacent to the base 41 is provided with an inclined surface 44A. An angle is formed between the inclined surface 44A and the extension arm 43. In some embodiments, the supporting part 44 is provided with another inclined surface 44B. The inclined surface 44B is provided at the other end of the supporting part 44 away from the base 41.

In some embodiments, the elastic member 4′ may include two extension arms 43 and two supporting parts 44, and has an appearance generally in a shape of “C” when viewed from the first axis X direction. The two extension arms 43 are both connected to the base 41. The two supporting parts 44 are connected to the two extension arms 43, respectively. The two supporting parts 44 are deformably disposed in two elongated holes 314 of the side plate 31, respectively. In this way, interference or a sliding problem caused by inconsistent operating directions of the two extension arms 43 can be avoided when the first expansion card 301 or the second expansion card 302 is mounted. Each elastic member 4′ may be made of a metal material. This is not limited thereto.

In some embodiments, two elastic members 4′ may be disposed on the side plate 31, and the two elastic members 4′ are disposed on two ends of the side plate 31. In this way, when the electronic component 300 is inserted in the card insertion area 30A, the two elastic members 4′ can provide stable support force. Viewed from the first axis X direction, two elastic members 4′ have appearances in a shape of “C” and an appearance in a shape of reverse “C”, respectively. Extension arms 43 of the elastic members 4′ are located adjacent to each other and face each other. Bases 41 of the elastic members 4′ face each other and are away from each other.

In some embodiments, the elastic member 4′ includes a docking part 42 located at the base 41. The side plate 31 includes two fixing parts 312 and an elongated hole 314. The two fixing parts 312 are disposed on two ends of the side plate 31. A long axial direction of the elongated hole 314 is arranged in a same horizontal direction as a card insertion direction of the card insertion area 30A. The elongated hole 314 is located between the two fixing parts 312. The docking part 42 of the elastic member 4′ is located at one of the two fixing parts 312. The fixing part 312 includes a circular raised ring 312 (the circular raised ring 312 is given a same sign as the fixing part 312 below). The docking part 42 includes a joint hole 42 (the joint hole 42 is given a same sign as the docking part 42 below). The circular raised ring 312 is riveted to the joint hole 42. This is not limited thereto. The supporting part 44 of the elastic member 4′ is deformably disposed in the elongated hole 314 of the side plate 31. In some embodiments, two elongated holes 314 are provided on the side plate 31, and can accommodate the two supporting parts 44 of the elastic member 4′, respectively. In some embodiments, the elastic member 4′ is disposed on one side surface of the side plate 31 (not indicated) via the docking part 42. The supporting part 44 penetrates through the elongated hole 314, projects from the other side surface of the side plate 31 (not indicated), and is located in the card insertion area 30A.

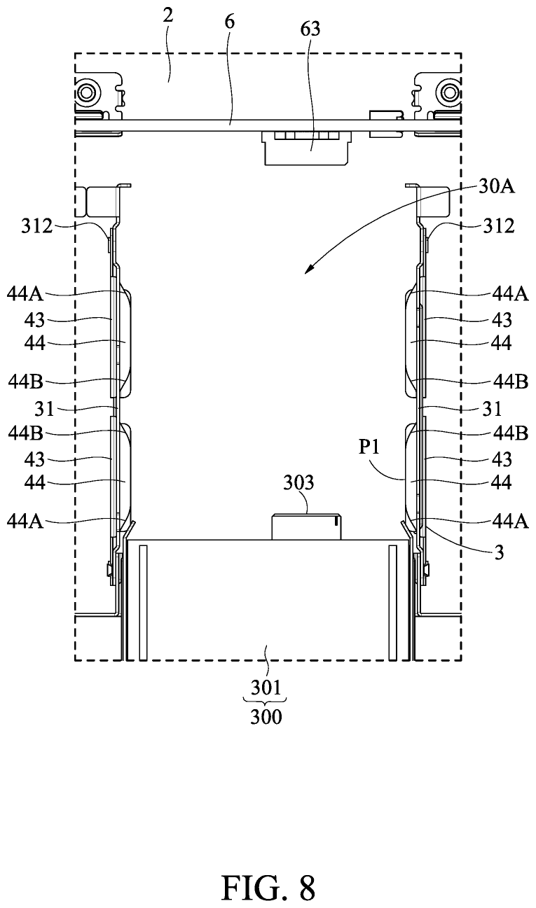

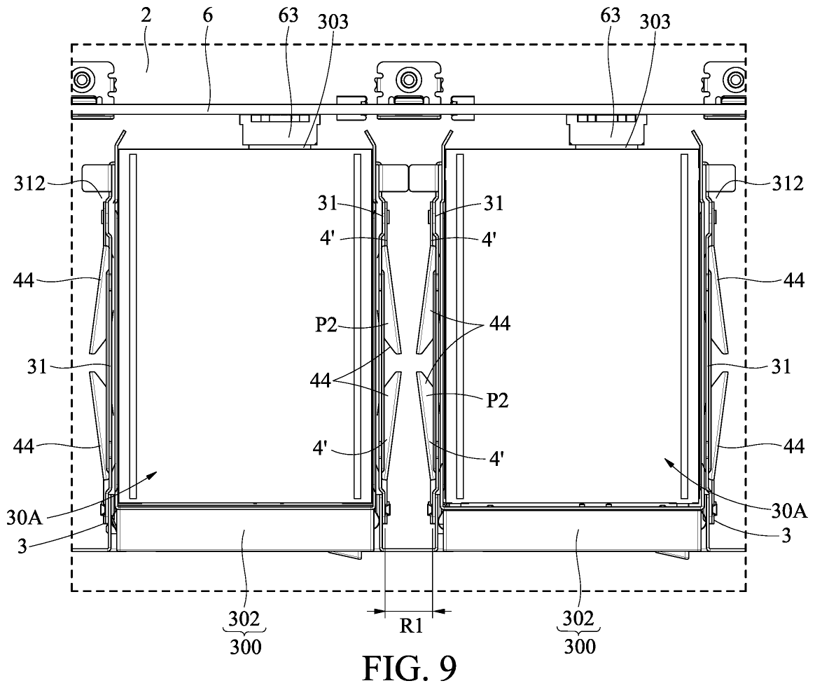

Refer to FIG. 7 to FIG. 9. FIG. 8 is a schematic partial top view of an electronic device 100, and shows a state of an electronic component 300 prepared to be inserted in a card insertion area 30 A and abutting against elastic members 4′. FIG. 9 is a schematic partial top view of an electronic device 100, which shows a state of an electronic component 300 inserted in a card insertion area 30A and abutting against elastic members 4′. The following is described by using an example in which a side plate 31 includes two elastic members 4′. One elastic member 4′ is disposed at a position on the side plate 31 located adjacent to an insertion slot 30C. The other elastic member 4′ is disposed at a position on the side plate 31 away from the insertion slot 30C (located adjacent to a back plate 6). A supporting part 44 of the elastic member 4′ is located at a first position P1. An elongated hole 314 restricts freedom of reciprocating displacement of the supporting part 44 of the elastic member 4′ during moving, to prevent the supporting part 44 of the elastic member 4′ from falling off from the elongated hole 314.

Refer to FIG. 7 to FIG. 9. When the electronic component 300 is the first expansion card 301 inserted in the card insertion area 30A, the supporting parts 44 of the elastic member 4′ are located at the first position P1 and support the bottom of the first expansion card 301, so that the supporting parts 44 firmly support the first expansion card 301. When the electronic component 300 is the second expansion card 302 inserted in the card insertion area 30A, during a card insertion process, the second expansion card 302 pushes the inclined surface 44A of the supporting part 44 of the elastic member 4′ located adjacent to the insertion slot 30C to move the supporting part 44 of the elastic member 4′ to a second position P2 in a direction away from the card insertion area 30A. Then, when the second expansion card 302 continues to be inserted into the card insertion area 30A, the second expansion card 302 pushes the inclined surfaces 44B of the supporting parts 44 of the other elastic member 4′ that is away from the insertion slot 30C, to move the supporting parts 44 of the other elastic member 4′ to the second position P2 in a direction away from the card insertion area 30A. In this case, the supporting parts 44 of the two elastic members 4′ move away from the side plates 31 and the card insertion area 30A. The supporting parts 44 of the elastic members 4′ are pushed from the first position P1 to the second position P2, so that the supporting parts 44 can firmly hold side edges of two sides of the second expansion card 302.

As shown in FIG. 9, there is a preset first spacing R1 between two adjacent baffle assemblies 3. The preset first spacing R1 provides enough space for supporting parts 44 on adjacent side plates 31 to move from the first position P1 to the second position P2 without affecting each other due to collision during moving towards each other. In this way, the first expansion card 301 and the second expansion card 302 can be flexibly mounted in a same card insertion area 30A of a same expansion assembly 200.

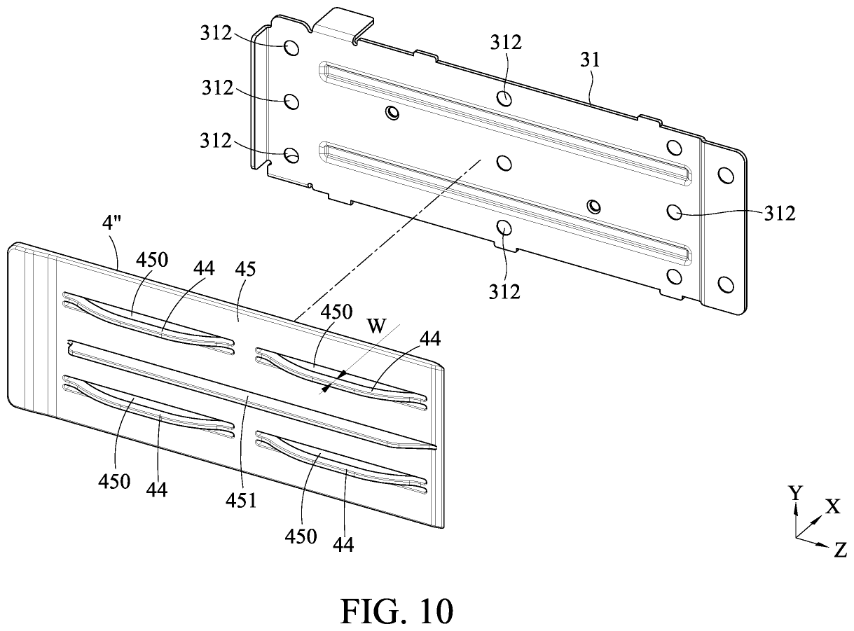

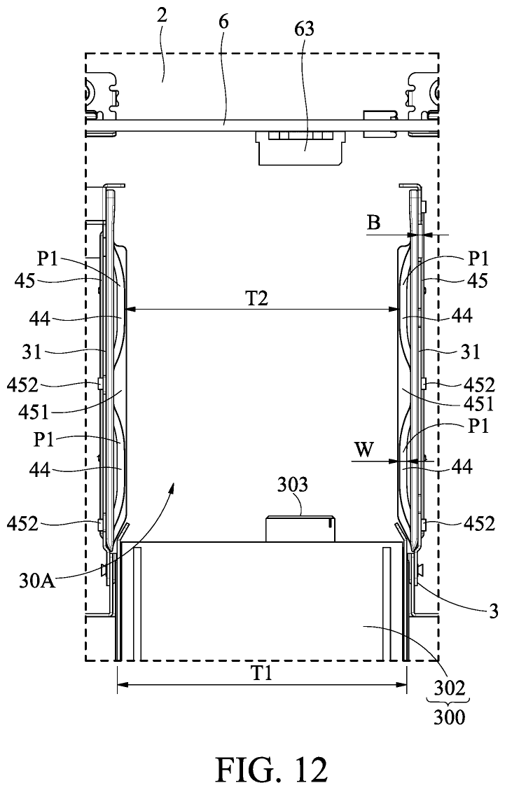

FIG. 10 is a schematic front exploded view of a baffle assembly 3, including an elastic member 4″. The elastic member 4″ includes supporting parts 44 and a docking plate 45. Two ends of each supporting part 44 are connected to the docking plate 45. A middle part of the supporting part 44 (not shown) is away from the docking plate 45 in the first axis X direction, to form an elastic arm. This is not limited thereto. In some embodiments, one end of the supporting part 44 is connected to the docking plate 45, and the other end of the supporting part 44 is a free end and is away from the docking plate in the first axis X direction, to form a cantilever (as shown in FIG. 14 and FIG. 15). In some embodiments, the supporting part 44 is generally in a trapezoid shape or an arch-bridge shape when viewed from the second axis Y direction. An arm thickness W of the supporting part 44 is 2 mm. The docking plate 45 is disposed on one side surface of the side plate 31. The supporting part 44 projects from the docking plate 45 towards the other side plate 31 (as shown in FIG. 12).

In some embodiments, the docking plate 45 is disposed on the side plate 31. A second slide rail 451 is disposed on the docking plate 45. The second slide rail 451 is a transverse plate extending along the third axis Z direction (a card insertion direction). The second slide rail 451 may project from one side surface of the docking plate 45 towards the other side plate 31 along the first axis X. The second slide rail 451 is located adjacent to the supporting part 44, so that the electronic component 300 can be firmly positioned after being inserted in the card insertion area 30A. In some embodiments, the second slide rail 451 is disposed between two supporting parts 44 arranged in the second axis Y direction. The second slide rail 451 has a same function as the first slide rail 311, and can support two sides of the first expansion card 301 or the second expansion card 302. In some embodiments, the second slide rail 451 may be omitted and the elastic member 4″ may be disposed at a corresponding position.

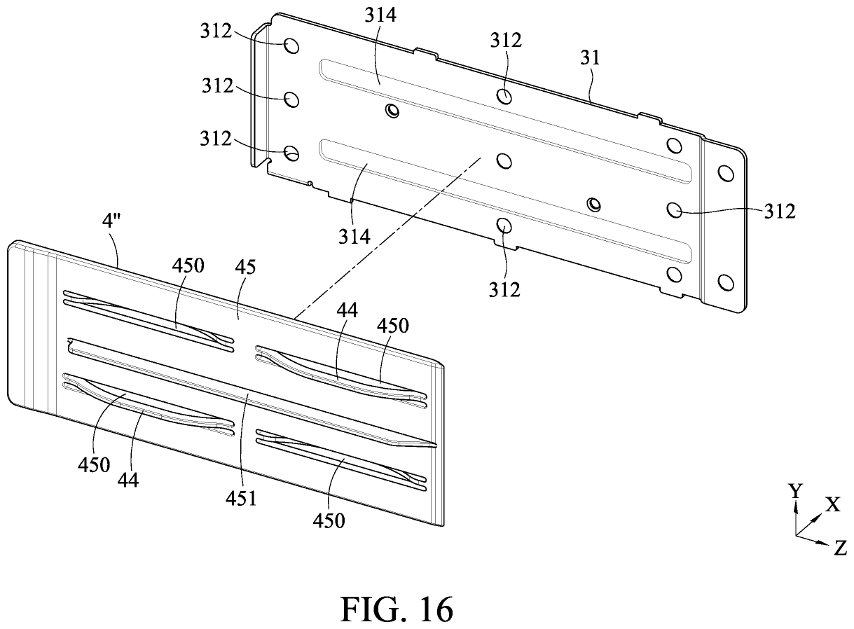

In some embodiments, the docking plate 45 may be provided with four supporting parts 44. The four supporting parts 44 are arranged in an array. Each supporting part 44 projects from one side surface of the docking plate 45 towards the first axis X direction. This is not limited thereto. In some embodiments, the supporting parts 44 respectively project from two side surfaces of the docking plate 45 in the plus first axis X direction and the minus first axis X direction in a staggered manner (shown in FIG. 14 and FIG. 16, as described later).

In some embodiments, the four supporting parts 44 arranged in an array are arranged along the second axis Y direction and the third axis Z direction in a 2×2 array. This structure can avoid insufficient strength of the supporting parts 44 or deformation difficulty due to excessively long supporting parts 44, and prevent a sliding problem caused by interference when the first expansion card 301 and the second expansion card 302 are mounted.

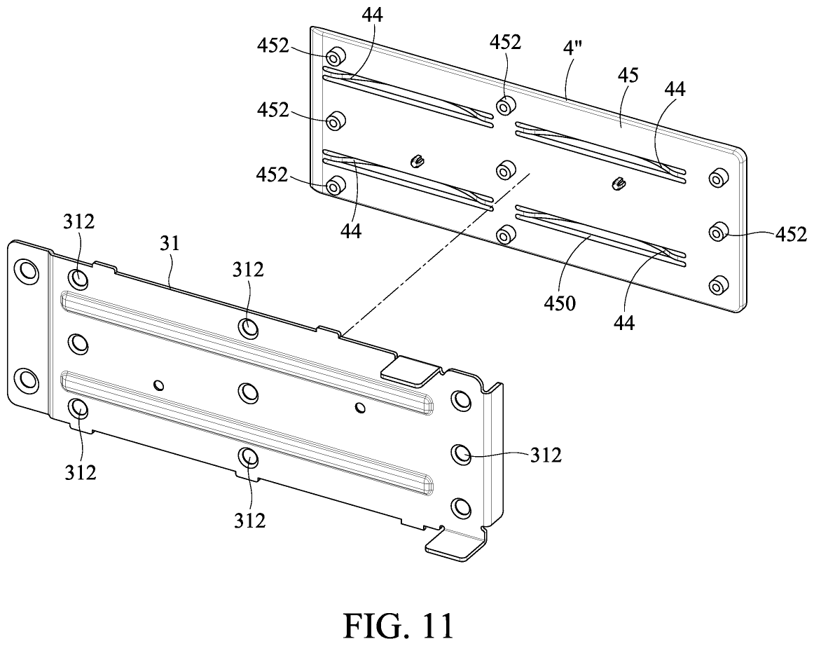

Refer to FIG. 10 and FIG. 11. FIG. 11 is a schematic rear exploded view of a baffle assembly 3. In some embodiments, a docking part 452 is disposed on the docking plate 45. The side plate 31 includes a fixing part 312. The docking part 452 is located at the fixing part 312. The fixing part 312 includes a joint hole 312 (the joint hole 312 is given a same sign as the fixing part 312 below). The docking part 452 includes a circular raised ring 452 (the circular raised ring 452 is given a same sign as the docking part 452 below). The circular raised ring 452 is connected to the joint hole 312. In some embodiments, the circular raised ring 452 and the joint hole 312 are fixed by hot melt processing. This is not limited thereto. In some embodiments, nine joint holes 312 are provided on the side plate 31. Three joint holes 312 form a group, and three groups of joint holes 312 are provided on two ends of the side plate 31 and a middle section between the two ends, respectively. Nine circular raised rings 452 are disposed on the docking plate 45 correspondingly. The nine joint holes 312 are respectively fixed on the nine circular raised rings 452 to firmly position the docking plate 45 on the side plate 31, to prevent the elastic member 4″ on docking plate 45 from falling off during moving. This is not limited thereto.

Refer to FIG. 10 to FIG. 12. FIG. 12 is a schematic partial top view of an electronic device 100, and shows a state of an electronic component 300 prepared to be inserted in a card insertion area 30A and abutting against elastic members 4″. In some embodiments, the elastic member 4″ is provided with four supporting parts 44 arranged in an array and a second slide rail 451, to divide the baffle assembly 3 into four card insertion areas 30A′. When two elastic members 4″ are respectively disposed on two side plates 31 of the baffle assembly 3, the supporting parts 44 project from the docking plates 45 in the card insertion areas 30A. In this case, the supporting parts 44 of the elastic member 4″ are located at a first position P1.

In some embodiments, when the electronic component 300 is the first expansion card 301 inserted in the card insertion area 30A, the supporting parts 44 are located at the first position P1 and support the bottom of two sides of the first expansion card 301, so that the supporting parts 44 firmly support the first expansion card 301.

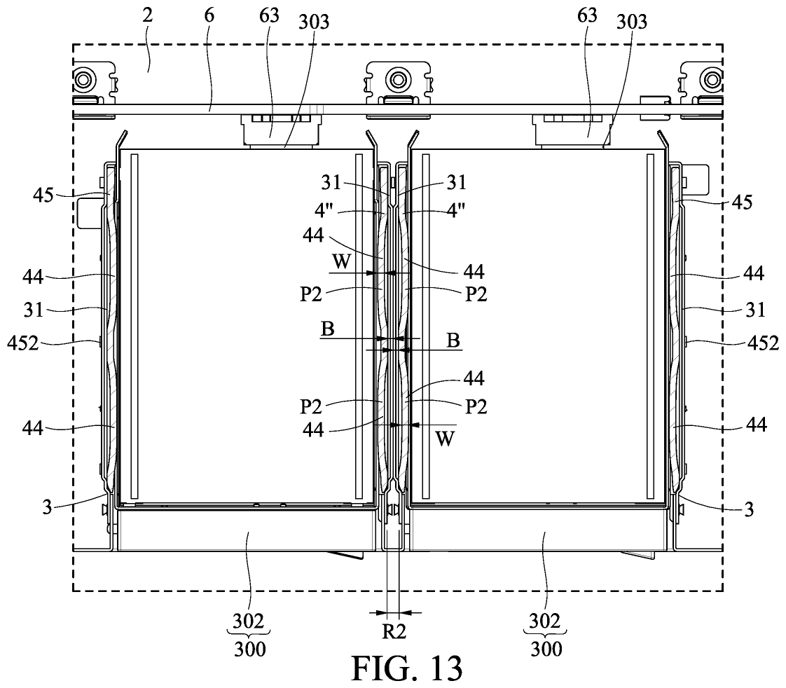

Refer to FIG. 10 to FIG. 13. FIG. 13 is a schematic partial top view of an electronic device 100, which shows a state of an electronic component 300 inserted in a card insertion area 30A and abutting against elastic members 4″. The electronic component 300 is the second expansion card 302 inserted in the card insertion area 30A. The supporting parts 44 on the side plates 31 are pushed by the second expansion card 302 to move from a first position P1 to a second position P2. The supporting parts 44 hold two sides of the second expansion card 302. In this way, the first expansion card 301 and the second expansion card 302 can be flexibly mounted in a card insertion area 30A defined by a same baffle assembly 3.

In some embodiments, to reduce a distance between the baffle assemblies 3, elastic members 4″ are provided, and two side plates 31 of two adjacent baffle assemblies 3 are substantially attached to each other. The elastic member 4″ is disposed on the side surface of one side plate 31 facing the other side plate 31. In other words, the elastic member 4″ is disposed in the card insertion area 30A, so that a distance between adjacent baffle assemblies 3 is reduced. In this way, in a same size specification of the electronic device 100, a plurality of baffle assemblies 3 with the elastic members 4″ can be provided to allow more electronic components 300 to be mounted, while achieving an effect of flexible mounting the first expansion card 301 or the second expansion card 302.

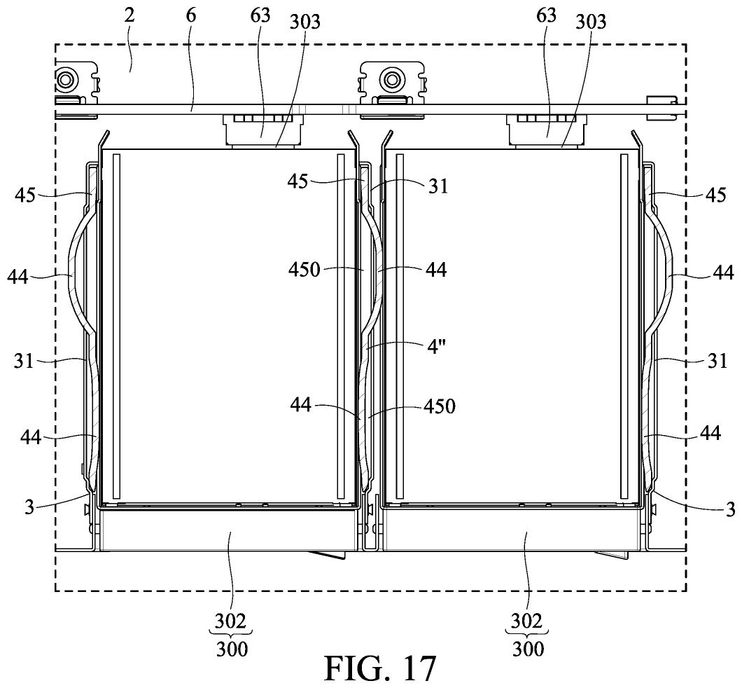

Refer to FIG. 14 to FIG. 17. FIG. 14 is a schematic exploded view of a baffle assembly 3, having an elastic member 4″ including a plurality of supporting parts 44 (which are of a cantilever structure) arranged in a staggered manner. FIG. 15 is a schematic partial top view of an electronic device 100, which shows a state of an electronic component 300 being inserted in a card insertion area 30A and abutting against each supporting part 44 having a cantilever structure. FIG. 16 is a schematic exploded view of a baffle assembly 3, having an elastic member 4″ including a plurality of supporting parts 44 (which are of an elastic arm structure) arranged in a staggered manner. FIG. 17 is a schematic partial top view of an electronic device 100, which shows a state of electronic components 300 being inserted in a card insertion area 30A and abutting against the supporting parts 44 having an elastic arm structure. In some embodiments, the supporting parts 44 of the elastic member 4″ may be disposed on two opposite side surfaces of the docking plate 45. An elongated hole 314 is disposed on the side plate 31 to accommodate the supporting parts 44. In this design, two adjacent baffle assemblies 3 may share one side plate 31 to reduce a distance between each baffle assembly 3.

As shown in FIG. 15, the baffle assembly 3 includes a third side plate 31c. The third side plate 31c is disposed between a first side plate 31a and a second side plate 31b, to divide the baffle assembly 3 into two card insertion areas 30A. The elastic member 4″ is disposed on the third side plate 31c. Four supporting parts 44 arranged in a 2×2 array are disposed on the elastic member 4″, and project from two opposite side surfaces of the docking plate 45 in a staggered manner in the two card insertion areas 30A, respectively. Specifically, one of the supporting parts 44 of the elastic member 4″ and another adjacent supporting part 44 are disposed on the two opposite side surfaces of the docking plate 45, respectively. In other words, one of the supporting parts 44 projects from the docking plate 45 towards the other side plate 31. Another supporting part 44 adjacent to the supporting part 44 projects from the docking plate 45 in a direction away from the other side plate 31. When the first expansion card 301 is inserted in the card insertion area 30A, the supporting parts 44 of the elastic member 4″ may abut against two ends (diagonal corners) of the first expansion card 301. When the second expansion card 302 is inserted in the card insertion area 30A, the supporting parts 44 of the elastic member 4″ may clamp at two ends (diagonal corners) of the second expansion card 302. The second slide rail 451 abuts against the bottom of the second expansion card 302. In this way, the baffle assembly 3 may share the third side plate 31c and the elastic member 4″, to reduce the distance between the baffle assemblies 3 and firmly support the first expansion card 301 or the second expansion card 302, thereby achieving a flexible mounting effect. In addition, more electronic components 300 may be mounted in a case of a same size specification of the electronic device 100.

In conclusion, according to some embodiments, the supporting parts of the elastic members are disposed on the plurality of side plates of the baffle assembly, so that the supporting parts are respectively located in card insertion areas to allow electronic components of different thicknesses to be separately inserted in card insertion areas in a same area of a same expansion assembly.

What is claimed is:

1. An expansion assembly, comprising:
a first baffle;
a second baffle, opposite to the first baffle; and
a baffle assembly, comprising two side plates opposite to each other and a plurality of elastic members disposed on each of the two side plates respectively, wherein the two side plates are connected to the first baffle and the second baffle, and each of the elastic member comprises a supporting part, and each of the supporting parts projects from one of the two side plates towards the other one of the two side plates.

2. The expansion assembly according to claim 1, wherein each of the two side plates comprises an elongated hole and a first slide rail, the first slide rail projects from one side surface of one of the two side plates towards the other one of the two side plates, the first slide rail is adjacent to the elongated hole, and the supporting part of one of the plurality of elastic members is deformably disposed in the elongated hole of one of the two side plates.

3. The expansion assembly according to claim 1, wherein each of the plurality of elastic members comprises two docking parts, and the two docking parts are respectively connected to two ends of the supporting part; and each of the two side plates comprises two fixing parts and an elongated hole, the two fixing parts are respectively disposed on two ends of each of the two side plates, the elongated hole is provided between the two fixing parts, the two docking parts are disposed on the two fixing parts, respectively, and the supporting part of each of the plurality of elastic members is deformably disposed in the elongated hole.

4. The expansion assembly according to claim 3, wherein the supporting part of each of the plurality of elastic member comprises a plurality of outer protrusion parts and a plurality of inner protrusion parts arranged alternately in sequence, each of the plurality of outer protrusion parts projects from one side surface of one of the two side plates towards the other one of the two side plates, and each of the plurality of inner protrusion part projects from the other side surface of one of the two side plates away from the other one of the two side plates.

5. The expansion assembly according to claim 1, wherein each of the plurality of elastic members comprises a base and an extension arm, the extension arm extends from the base, the supporting part extends from one side edge of the extension arm, and an angle is formed between the supporting part and the extension arm.

6. The expansion assembly according to claim 5, wherein the supporting part has an inclined surface, and an angle is formed between the inclined surface and the extension arm.

7. The expansion assembly according to claim 5, wherein each of the two side plates comprises two elongated holes arranged in sequence in a direction, each of the plurality of elastic members comprises two extension arms extending from the base, each of the two extension arms is provided with the supporting part, and the two supporting parts are deformably disposed in the two elongated holes, respectively.

8. The expansion assembly according to claim 1, wherein each of the plurality of elastic members comprises a docking plate, the docking plate is disposed on one side surface of one of the two side plates, and the supporting part projects from the docking plate towards the other one of the two side plates.

9. The expansion assembly according to claim 8, wherein two ends of the supporting part are connected to the docking plate to form an elastic arm.

10. The expansion assembly according to claim 8, wherein one end of the supporting part is connected to the docking plate, and the other end of the supporting part is a free end, which forms a cantilever.

11. The expansion assembly according to claim 8, wherein each of the plurality of elastic members comprises a second slide rail, the second slide rail projects from the docking plate towards the other one of the two side plates, and the second slide rail is adjacent to the supporting part.

12. The expansion assembly according to claim 1, wherein each of the plurality of elastic members comprises a docking plate and a plurality of supporting parts, the docking plate is disposed on one side surface of one of the two side plates, one of the supporting parts projects from the docking plate towards the other one of the two side plates, and another supporting part adjacent to the supporting part projects from the docking plate in a direction away from the other one of the two side plates.

13. The expansion assembly according to claim 12, wherein each of the two side plates comprises an elongated hole, and the supporting part of the elastic member is deformably disposed in the elongated hole.

14. The expansion assembly according to claim 12, wherein two ends of the supporting part are connected to the docking plate to form an elastic arm.

15. The expansion assembly according to claim 12, wherein one end of the supporting part is connected to the docking plate, and the other end of the supporting part is a free end, which forms a cantilever.

16. An electronic device, comprising:
an expansion assembly, comprising:
a first baffle;
a second baffle, opposite to the first baffle; and
a baffle assembly, comprising two side plates opposite to each other and a plurality of elastic members disposed on each of the two side plates respectively, wherein the two side plates are disposed between the first baffle and the second baffle, the first baffle, the second baffle, and the two side plates define a card insertion area, each of the elastic member comprises a supporting part, and each of the supporting parts projects from one of the two side plates towards the other one of the two side plates; and
an electronic component, used to be accommodated in the card insertion area and supported or clamped by the elastic members.

17. The electronic device according to claim 16, wherein the electronic component is a first expansion card or a second expansion card, and the supporting parts of the plurality of elastic members are used to support a bottom of the first expansion card or hold two sides of the second expansion card.

18. The electronic device according to claim 16, wherein the side plate comprises an elongated hole and a fixing part, and the elongated hole is adjacent to the fixing part; and the elastic member comprises a docking part, the docking part is disposed on the fixing part, and the supporting part is deformably disposed in the elongated hole.

19. The electronic device according to claim 16, wherein the elastic member comprises a docking plate, the docking plate is disposed on one side surface of one of the two side plates, and the supporting part projects from the docking plate towards the other one of the two side plates.

20. The electronic device according to claim 16, wherein the elastic member comprises a docking plate and a plurality of supporting parts, the docking plate is disposed on one side surface of one of the two side plates, one of the supporting parts projects from the docking plate towards the other one of the two side plates, and another supporting part adjacent to the supporting part projects from the docking plate in a direction away from the other one of the two side plates.
